(19) United States
(12) Patent Application Publication
(10) Pub. No.: US 2007/0253008 A1
(43) Pub. Date: Nov. 1, 2007

(54) Maintenance of accurate visual color performance of displays

(75) Inventors: Christopher J. Edge, St. Paul, MN (US); Dallas K. Pierson, Oakdale, MN (US)

Correspondence Address: Mark G. Bocchetti;Patent Legal Staff, Eastman Kodak Company, 343 State Street, Rochester, NY, 14650-2201, US

(73) Assignee: Eastman Kodak Company

(21) Appl. No.: 11/412,566

(22) Filed: Apr. 27, 2006

(51) Int. Cl. G03F 3/08

(52) U.S. Cl. 358/1.9; 358/518

(57) ABSTRACT

A system and a method are provided for maintaining accurate visual color performance of displays. In particular, various embodiments of the present invention described herein provide a system wherein partial color certification is incorporated into the calibration procedure. In the event that the partial color certification is out of tolerance, a full certification procedure is performed. If the full certification procedure is out of tolerance, the calculated errors of the certification procedure are utilized to perform an update to a baseline profile for the display. The updated baseline profile can either replace the existing baseline profile or can be concatenated with the baseline profile to preserve the baseline behavior of the display.

### FIELD OF THE INVENTION

This invention relates to the maintenance of accurate visual color performance of displays. In particular, this invention pertains to the adjustment of existing baseline RGB profiles and of conversions to those profiles to account for aging shifts of up to 20 delta E in RGB chromaticities of RGB displays, RGB projectors, and in the primary colorants of any digital imaging device with near additive color behavior.

### BACKGROUND OF THE INVENTION

Certain industries and workflows require highly accurate color reproduction and consistency when displaying or printing color images. Historically, the graphic arts have required extremely precise color control and reproduction ever since high quality color printing became commonly practiced. The medical industry historically has been generally less color critical, relying primarily on synthetic colors or “pseudo-colors”. However, the time may well be approaching when techniques for preserving color accuracy as described in this invention will be as critical for the medical industry as it is for the graphic arts.

This invention has been developed for use in virtual proofing systems, although it has applicability in any critical color imaging systems. Virtual proofing has been explained in white papers such as “Matchprint™ Virtual Proof: Technical White Paper”, published at the web site www.kpg.com in mid-2002. The more generic term “Soft Proofing” has been used to describe viewing images and files on a display with a greater or lesser similarity to the corresponding printed matter that results when printing the file. “Virtual Proofing” further refines this concept to include a near-perfect visual match between the image on the display and corresponding printed matter. This match includes overall color appearance, white and gray balance, paper simulation, contrast, perceived detail, and the saturations and hues of saturated colors such as fruit as well as less saturated but highly sensitive colors such as skin tones.

In order to achieve this result, several technical barriers must be overcome:
1) color measurements from printed matter must be corrected before rendering to display as described in U.S. Patent Application Publication No. 2002/0167528 “Correction techniques for soft proofing” by Edge;
2) calibration of each display must be sufficiently accurate as described in U.S. Pat. No. 6,775,633 “Calibration Techniques for Imaging Devices” by Edge; and
3) the infrastructure of the architecture must be sufficient to ensure accurate remote viewing of color as described in U.S. Patent Application Publication No. 2003/0122806 “Soft Proofing System” by Edge.
   There are two general approaches to creating profiles for devices used in proofing, both display devices as well as ink jet devices. The first approach is to build a profile based on a recently measured data set with no regard to previous data sets or profiles built for that device or similar devices. The second approach is to build a baseline profile or master profile for one device or a representative population of a particular model of a device and attempt to recalibrate that device(s) in the future to maintain the characterized state.

Recalibration may entail optimizing one dimensional LUTs as described in the above referenced '528 patent Application Publication by Edge, or may entail a partial multi-dimensional correction as practiced in the ColorZone calibration feature of the Iris Ink Jet Proofing System (a currently discontinued system originally sold by Iris™, Scitex™, and later Creo™) and the Veris™ Ink Jet Proofing System (a 2^{nd} generation system currently sold by Kodak™). The mapping algorithm for this latter approach was based on the simplified color management approach described in U.S. Pat. No. 5,315,380 by Ingraham et al.

The Edge '633 patent describes a one-dimensional LUT adjustment for displays that, in particular, optimizes gray balance using a limited number of parameters for defining the correction. This adjustment is required in order to minimize the risk of introducing noise and artifacts. This adjustment, as deployed in the Matchprint™ Virtual Calibrator sold by Eastman Kodak Company, assumes the existence of a baseline profile created in the manner described above—either by careful measurement of a representative device or of a population of similar devices. It is assumed that after calibration, the resulting state of the device will be identical to the baseline characterization made previously, within the known variability of the population. If the device behaves in a nearly additive manner with regard to color (within 1-2 delta E) and can be well-approximated by a matrix TRC formalism as defined in the document “Specification ICC. 1:2001-04” available at www.color.org, then the distribution of the population can be indicated by determining the population distribution of merely the RGB primaries, i.e. R=255, G=0, B=0 for red, etc. If this population distribution, as described using a visually uniform metric such as ΔE, known in the art, is considered acceptable, then indeed using a baseline profile is sufficient. If this assumption is proven not to be valid, a baseline profile can still be used, but some form of multi-dimensional correction will need to be deployed in order to preserve the original baseline behavior. This multi-dimensional correction is the approach of the ColorZone technology utilized for the ink jet proofing systems mentioned above. However, this approach typically requires a significant sampling of data in order to achieve a reasonable partial-multi-dimensional correction. Furthermore, this approach is generally performed as a separate calibration procedure performed by the user if the user determines that the color accuracy of the device is not satisfactory. For example, the user may measure the colors defined for a SWOP certification and determine that the errors are outside of the required range. The user would run the ColorZone procedure, which would create charts sampling the full gamut range of colors in order to bring the device back to the state defined by the baseline profile. “Full gamut range” is meant to refer to the boundary conditions of the device, for example, C=100%, M=0%, Y=0%, K=0%, and all other permutations of solid CMY, as well as a variety of tint values both single colorant and mixed colorant samples.

Experience has shown that although an initial population of displays may have an acceptable ΔE distribution for the RGB colorants, individual displays may shift in the colorant properties with age. It has been observed that LCDs become less bright and become yellow with age. Furthermore, changes in manufacturing may cause an entire population of displays to vary the measured colorant values by 5 to 10 ΔE. If this is the case, then mere one dimensional calibration of the RGB LUT's will not suffice. Some form of multi-dimensional correction will be required to preserve the baseline behavior.

A standard color management approach that would be obvious to those familiar with this technology would be to create a new profile using standard profiling techniques. This approach typically entails measuring a sampling of the color gamut of the device, building a gamut map, etc., to define the new color characterization of the device. This profile could either replace the baseline profile, or could be concatenated with the baseline profile in order to preserve the color properties of the device.

There are several risks and difficulties with this approach. For example,
1) creating a new profile directly from measured data, as opposed to performing a controlled adjustment of an existing profile, is a complex task which can be prone to error due to the impact of measurement noise, interpolation errors, etc., and
2) different measurement devices can demonstrate significant device-to-device differences when measuring the same color, especially if they are different types of device such as spectrophotometers vs. colorimeters.

The second risk identified above implies that there may be significant errors introduced between displays if they are profiled using different devices and especially different types of measurement devices. The impact of device-to-device error can be greatly reduced if only one accurate device or device type is used to create the baseline profile. This approach also enables careful averaging of data, as well as careful construction and validation of the baseline profile by the vender of the virtual proofing system. The impact of device-to-device measurement error can be kept to a minimum by using the local measurement device to measure shifts or differences in color values from reference measurements performed with a similar device, and then correcting the baseline profile based on those shifts. As mentioned above, this corrected profile can either substitute for the baseline profile, or be concatenated with the baseline profile in order to preserve the color characterization of the device. Accordingly, a need in the art exists for a simple and efficient way to maintain, as accurately as possible, visual performance of devices, such as displays, throughout their lifecycle.

### SUMMARY OF THE INVENTION

The above-described problem is addressed and a technical solution is achieved in the art by a system and a method for maintaining accurate visual color performance of displays according to the present invention. In particular, the various embodiments of the present invention described herein provide maintenance of accurate visual color performance of displays without the use of complex selective color adjustment techniques used in the prior art, such as the ColorZone approach or standard profile construction methods. In an embodiment of the present invention, an RGB->(RGB)′ matrix correction is applied to original RGB values of a display resulting from a CMYK->RGB_{(baseline)} conversion in order to retain original baseline profile properties of the display. According to an embodiment of the present invention, the RGB->(RGB)′ matrix correction is a 3×3 matrix correction. Some advantages of this approach are that 1) very few measurements are required in order to calculate a successful correction to the RGB values, and 2) no artifacts will result after correction due to the simplicity of the RGB correction matrix formalism used.

According to another embodiment of the present invention, the RGB->(RGB)′ matrix correction applied is determined based at least upon measured color shifts of a display, and a least squares fit is performed on the measured color shifts of the display, which may be used to update the original baseline profile properties of the display. Advantages of this approach include, in addition to the advantages above, a correction that is substantially unaffected by measurement noise or measurement error, and a correction that can easily be validated by determining whether a deviation between the corrected RGB values and the original RGB values is within a predetermined range or threshold by the quality of fit to the data prior to applying the correction.

According to a further embodiment of the present invention, a certification check is performed to determine whether the display is in tolerance for both chromatic and neutral colors. If it is determined that the display is not in tolerance, then a RGB->(RGB)′ matrix, according to an embodiment of the present invention, is performed on the display to place its original baseline profile properties back in tolerance. The advantages of this approach include, in addition to the advantages described above, that daily calibrations of the display can include minimal measurement information to confirm certification with minimal loss of time as compared to conventional schemes, and in the event of unacceptable results, the update procedure can be engaged automatically without user intervention.

According to still another embodiment of the present invention, the system concatenates the updated original baseline profile properties with the original baseline profile properties in order to generate the necessary RGB->(RGB)′ correction. Advantages of this approach include, in addition to the above advantages, that interpolation and round-off error can be minimized as well as time required to convert pixels.

According to yet another embodiment of the present invention, certification measurements, such as those documented in a SWOP Application Data Sheet (ADS) for the display, are used to characterize the measured color shifts and to confirm that the measured color shifts have been adequately resolved once the RGB->(RGB)′ matrix correction has been performed. Advantages of this approach include, in addition to the previous advantages, that 1) the measurements for certification can be the same data as the measurements for calculating the correction, and 2) there is a guarantee that the display will be within specification relative to a certification standard after the correction is performed.

In addition to the embodiments described above, further embodiments will become apparent by reference to the drawings and by study of the following detailed description.

### BRIEF DESCRIPTION OF THE DRAWINGS

The present invention will be more readily understood from the detailed description of exemplary embodiments presented below considered in conjunction with the attached drawings, of which:

FIG. 1 illustrates a system for maintaining accurate visual color performance of displays, according to an embodiment of the present invention;

FIG. 2 illustrates a method, according to an embodiment of the present invention, for determining whether an update procedure should be performed on a baseline profile, invoking an update procedure if necessary, and for confirming that the update was successful; and

FIG. 3 illustrates an update procedure, according to an embodiment of the present invention, that may be utilized in response to the method of FIG. 2.

It is to be understood that the attached drawings are for purposes of illustrating the concepts of the invention and may not be to scale.

### DETAILED DESCRIPTION

Having determined that updating a baseline profile within a population of similar devices, such as displays, is advantageous, the next question to be answered is how to update that baseline profile in an effective and efficient manner. An objective of this invention is to describe such an effective and efficient method for updating a baseline profile. Several of the assumptions of this invention are as follows: (Note that the term “certified process” is used to denote a process such as is described in the SWOP ADS whereby a predetermined set of CMYK simulated colors on the display are measured, compared to archived reference values, differences are calculated, and a determination is made of whether the display in question is within acceptable tolerances.)
1) Whenever a display is calibrated, a system for monitoring and updating that display's profile should perform adequate measurements of the display's RGB colors to determine whether the display is performing within an adequate range of the baseline profile (“is in tolerance”);
2) the determination should be adequate to ensure that if a more extensive check is performed (such as measuring the colors required for the certified process), the display will be within acceptable tolerances;
3) the system should use a minimal sampling of RGB measurements when determining whether the display is in tolerance;
4) the system should update the baseline profile if it is determined that the display is out of tolerance by measuring a standard set of relevant colors such as the CMYK colors of a certified process;
5) the updating of the baseline profile should be based at least upon calculated differences between current measured values of the certified process and reference measured values for that certified process using the same measurement device type or equivalent device type; and
6) upon completion of the baseline profile update process, the system should confirm that the updated profile can be used successfully to achieve the targeted values of the certified process.

Advantages of designing a solution based on these assumptions include:
1) the time to calibrate the display's baseline profile remains short even though accurate confirmation is being performed each time to ensure that the display in question is in a certified state;
2) the errors which indicate that the display is no longer within tolerance are used to drive the correction of the baseline profile;
3) the same measurements are used to confirm the successful update of the baseline profile;
4) display-to-display differences between measurement devices have minimal impact on the consistency of the resulting updated RGB profile; and
5) because this approach is a relatively small magnitude correction to an existing profile, the correction can be performed with a minimal number of correction parameters (e.g., a 3×3 matrix), thereby ensuring good integrity of the final updated RGB profile.

A virtual proofing system, such as InSite™, PressProof™, or RealTimeProof™ with Matchprint™ Virtual (MV) technology, achieves accurate visual representation of hard copy proofs viewed under controlled lighting by performing a correction on device independent color data to compensate for the deficiencies of existing colorimetry. Normal color conversions (ICC in particular) are of the form CMYK->Lab->RGB. MV adds a correction that ensures a good visual match between hard copy proofs and the corresponding file displayed with MV. This can be described by the sequence CMYK->Lab->(Lab)′->RGB. The nature of the Lab->(Lab)′ correction for most displays is of the form:

Lab->XYZ->(XYZ)′->(Lab)′
where the XYZ correction is a simple matrix correction:

$$( \begin{matrix}{X}^{′} \\ {Y}^{′} \\ {Z}^{′}\end{matrix} ) = {M}_{c} ( \begin{matrix}X \\ Y \\ Z\end{matrix} ) \qquad Eq . 1$$

where M_{c} is the correction matrix to account for visual discrepancies. If corrections to the white point are addressed separately from corrections to the chromatic RGB colors, the corrections can be rolled into the Matrix/TRC formalism for the profile of the display (note that a D50 white point is assumed):

$$\begin{matrix}( \begin{matrix}{X}^{′} \\ {Y}^{′} \\ {Z}^{′}\end{matrix} ) = {M}_{XYZ \to {XYZ}^{′}} ( \begin{matrix}X \\ Y \\ Z\end{matrix} ) & Eq . 2 \\ = {M}_{XYZ \to {XYZ}^{′}} {M}_{RGB \to XYZ} ( {x}_{r} , {y}_{r} , {x}_{g} , {y}_{g} , {x}_{b} , {y}_{b} ) ( \begin{matrix}R \\ G \\ B\end{matrix} ) & Eq . 3 \\ \begin{matrix} = {M}_{RGB \to {XYZ}^{′}} ( {x}_{r} + Δ {x}_{r} , {y}_{r} + Δ {y}_{r} , {x}_{g} + Δ {x}_{g } , {y}_{g} + \\ = Δ {y}_{g} , {x}_{b} + Δ {x}_{b} , {y}_{b} + Δ {y}_{b} ) ( \begin{matrix}R \\ G \\ B\end{matrix} )\end{matrix} & Eq . 4\end{matrix}$$

For displays that are somewhat non-additive in their color behavior, or to address non-linear issues in the definition of the CIEXYZ observer functions, a selective adjustment linear in XYZ space can be deployed using the linear RGB device values:

$$( \begin{matrix}{X}^{′} \\ {Y}^{′} \\ {Z}^{′}\end{matrix} ) = {M}_{RGB \to {XYZ}^{′}} ( \begin{matrix}R \\ G \\ B\end{matrix} ) + ( \begin{matrix}Δ X ( R , G , B ) \\ Δ Y ( R , G , B ) \\ Δ Z ( R , G , B )\end{matrix} ) \qquad Eq . 5$$

$$where \\ ( \begin{matrix}Δ X ( R , G , B ) \\ Δ Y ( R , G , B ) \\ Δ Z ( R , G , B )\end{matrix} ) = {\sum }_{i = 0}^{i = 5} {β}_{i } ( R , G , B ) ( \begin{matrix}Δ X ( {R}_{i} , {G}_{i} , {B}_{i} ) \\ Δ Y ( {R}_{i} , {G}_{i} , {B}_{i} ) \\ Δ Z ( {R}_{i} , {G}_{i} , {B}_{i} )\end{matrix} )$$

$$where i = 0 , … 5 denotes R , G , B , C , M , Y$$

and βᵢ(R, G, B) is calculated as follows:
RGBₘᵢₙ=min(R,G,B)
βᵢ(R,G,B)=R−max(G,B) for i=R,R>G,R>B
βᵢ(R,G,B)=0 for i=R,R<G or R<B
βᵢ(R,G,B)=G−max(R,B) for i=G,G>R,G>B
βᵢ(R,G,B)=0 for i=G,G<R or G<B
βᵢ(R,G,B)=B−max(R,G) for i=B,B>G,B>R
βᵢ(R,G,B)=0 for i=B,B<G or B<R
βᵢ(R,G,B)=min(G,B)−RGBₘᵢₙ for i=C,R<G,R<B
βᵢ(R,G,B)=0 for i=C,R>G or R>B
βᵢ(R,G,B)=min(R,B)−RGBₘᵢₙ for i=M,G<R,G<B
βᵢ(R,G,B)=0 for i=M,G>R or G>B
βᵢ(R,G,B)=min(R,G)−RGBₘᵢₙ for i=Y,B<G,B<R
βᵢ(R,G,B)=0 for i=Y,B>G or B>R Eq. 6

In the event of shifts in the measured chromaticities of a display from the baseline characterization, the above corrections may no longer achieve adequate color appearance. Furthermore, values of Lab measured for purposes of certification (i.e., comparing with reference Lab values of various colors) may no longer be in specification. In fact, even if the shift is corrected in the profile, if the shift occurs in such a way as to bring certain reference colors in gamut that formerly were out of gamut, the resulting measured values may no longer be in specification relative to the original accepted reference values.

Thus, embodiments of this invention endeavor to update the baseline profile which includes the visual corrections when non-zero values of chromaticity shifts (δxᵣ, δcᵣ, δx_{g}, δy_{g}, δx_{b}, δy_{b}, small “δ” referring to measured shifts, large “Δ” referring to visual corrections) are detected. According to an embodiment of the present invention, a gamut restriction is employed to ensure that colors that were formerly slightly out of gamut will remain the same for the sake of consistency.

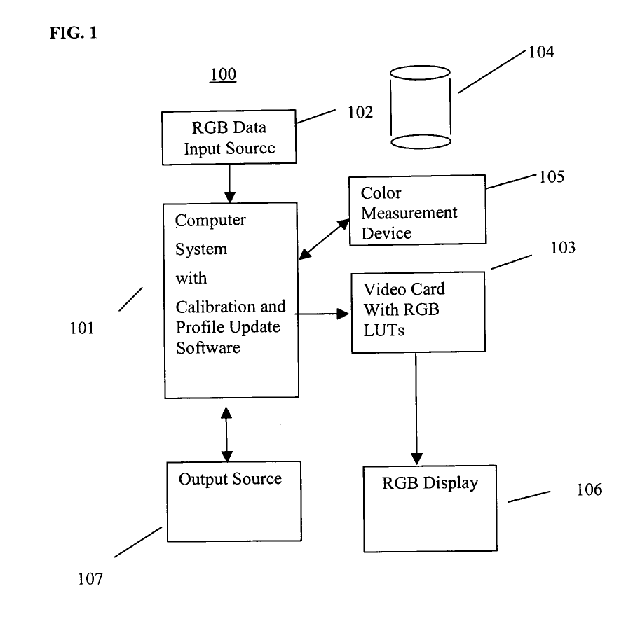

Turning now to FIG. 1, a system 100 for maintaining accurate visual color performance of an additive color display 106, such as an RGB display, according to an embodiment of the present invention, is illustrated. Various embodiments of the present invention, described below, involve inventive data processing techniques that may be executed by the system 100. The system 100 includes a computer system 101, that itself may include one or more computers, some or all of which may be communicatively connected. The system 100 also includes a color measurement device 105 which may be communicatively connected to the computer system 101 and which is configured to measure colors displayed by the RGB display 106. A video card 103 in the computer system 101 may be used to control operation of the display 106.

The data required to execute the below-described data processing techniques may be provided to the computer system 101 from an input source 102 communicatively connected to the computer system 101. Although one skilled in the art will appreciate that the invention is not limited to any particular input source 102, such input source may include one or more user-interfaces, such as keyboards, mice, etc., other computers, or computer accessible memories that may have data stored therein or thereon. In this regard, the color measurement device 105 may be included in the input source 102.

To facilitate executing the data processing techniques described below, the computer system 101 may have a data storage system 104 communicatively connected to it. The data storage system 104 may include one or more computer accessible memories that retain data and software configured to maintain accurate visual performance of the display 106. The data-storage system 104 may be a distributed data-storage system including multiple computer-accessible memories communicatively connected via a plurality of computers and/or devices. On the other hand, the data storage system 104 need not be a distributed data-storage system and, consequently, may include one or more computer-accessible memories located within a single computer or device.

The output(s) generated by the computer system 101 as a result of executing the data processing techniques described below may be transmitted to an output source 107 communicatively connected to the computer system 101. Although one skilled in the art will appreciate that the invention is not limited to any particular output source 107, such output source 107 may include one or more display devices, other computers, or computer-accessible memories that may have data stored therein or thereon. Accordingly, one skilled in the art will appreciate that the display 106 may be included in the output source 107. Further, the output source 107 may be included, completely or partially, within the data-storage system 104, to the extent that it includes one or more computer-accessible memories.

The phrase “computer-accessible memory” is intended to include any computer-accessible data storage device, whether volatile or nonvolatile, electronic, magnetic, optical, or otherwise, including but not limited to, floppy disks, hard disks, Compact Discs, DVDs, flash memories, ROMs, and RAMs.

The term “computer” is intended to include any data processing device, such as a desktop computer, a laptop computer, a mainframe computer, a personal digital assistant, a Blackberry, and/or any other device for processing data, and/or managing data, and/or handling data, whether implemented with electrical and/or magnetic and/or optical and/or biological components, and/or otherwise.

The phrase “communicatively connected” is intended to include any type of connection, whether wired, wireless, or both, between devices, and/or computers, and/or programs in which data may be communicated. Further, the phrase “communicatively connected” is intended to include a connection between devices and/or programs within a single computer, a connection between devices and/or programs located in different computers, and a connection between devices not located in computers at all. In this regard, although the data storage system 104 is shown separately from the computer system 101, one skilled in the art will appreciate that the data storage system 104 may be stored completely or partially within the computer system 101.

The data processing techniques, according to various embodiments of the present invention, begin with the observation that the RGB->XYZ matrix M_{RGB->XYZ′} in equation 4 (which has been corrected to account for visual discrepancy) is given as the product of the XYZ->(XYZ)′ visual correction matrix M_{XYZ->XYZ′} and the RGB->XYZ matrix M_{RGB->XYZ} (derived from measurement) indicated in equation 3. This observation can be used to determine the calculation for the new matrix M_{RGB->XYZ′} adjusted for both visual correction and for shift in chromaticities:

$$\begin{matrix} {M}_{RGB \to {XYZ}_{VisCorr}} = {M}_{{XYZ}_{VisCorr}} {M}_{RGB \to {XYZ}_{Meas}} \\ {M}_{{XYZ}_{VisCorr}} = {M}_{RGB \to {XYZ}_{VisCorr}} {M}_{RGB \to {XYZ}_{Meas}}^{- 1} \\ {M}_{ RGB \to {XYZ}_{VisCorrUpdate}} = {M}_{{XYZ}_{VisCorr}} {M}_{RGB \to {XYZ}_{MeasUpdate}} \\ = {M}_{RGB \to {XYZ}_{VisCorr}} {M}_{RGB \to {XYZ}_{Meas}}^{- 1} {M}_{RGB \to {XYZ}_{MeasUpdate}} \end{matrix} \qquad Eq . 7$$

Note that all the matrices in Eq. 7 are based on the same RGB->XYZ matrix with deltas added to the chromaticities of R, G, and B. The deltas to account for visual discrepancies are denoted by “Δxᵣ, Δyᵣ” etc. while the corrections to account for measurement based changes are denoted by “δxᵣ, δyᵣ”, etc. The same RGB->XYZ matrix as a function of the deltas M(Δxᵣ, Δyᵣ, Δx_{g}, Δy_{g}, ΔX_{b}, Δy_{b}) can be used. The chromaticities that define the matrix are fixed. The deltas indicate the corrections that are added to the respective RGB chromaticities:

$$\begin{matrix}\begin{matrix}{M}_{RGB \to {XYZ}_{VisCorrUpdate}} = M ( Δ {x}_{r} , Δ {y}_{r} , Δ {x}_{g} , Δ {y}_{g} , Δ {x}_{b} , Δ {y}_{b ,} ) \times \\ {M}^{- 1} ( 0 , 0 , 0 , 0 , 0 , 0 ) \times \\ M ( δ {x}_{r } , δ {y}_{r} , δ {x}_{g} , δ {y}_{g} , δ {x}_{b} , δ {y}_{b} )\end{matrix} & Eq . 8 \\ \begin{matrix}{M}_{RGB \to {XYZ}_{VisCorrUpdate}} = M ( {Δ}_{Vis} , Δ {y}_{Vis} ) \\ = {M}^{- 1} ( 0 , 0 ) M ( δ {x}_{Meas } , δ {y}_{Meas} )\end{matrix} & Eq . 9\end{matrix}$$

Note that if the matrix in equation 8 containing the visual corrections Δx_{Vis}, Δy_{Vis}, etc. is actually the more complex visually corrected function described in equation 5, the only change in equation 9 is that this matrix function would operate upon the result of multiplying M⁻¹ (0)M(δ).

It is assumed that the baseline measurement-based matrix M (0,0) is the result of careful averaging of a population of a particular type of display. It is also assumed that the visual corrections Δx_{Vis}, Δy_{Vis} have been confirmed as effective on a population of those same displays. Thus, the matrix M (Δx_{Vis}, Δy_{Vis}) is the visually corrected baseline profile for that population of displays. In the event of a measured shift from the original measured chromaticities, the calculation indicated in equation 9 should result in a new visually accurate baseline profile.

However, it is also often desirable to maintain consistency of color for a given display both visually and numerically. In the example of SWOP TR001 yellow, conversions with some displays result in clipped values of RGB that are lower in chroma (C*) than the SWOP yellow target value by 5-10 ΔE. Shifts in chromaticity due to aging for nearly all LCD displays appear to be in the direction of yellow. As a result, colors that used to be out of gamut by 5-10 ΔE may now be nearly in gamut. This means that if the only modification to the display's color characteristics is to update the display's RGB profile, there may be an increase in chroma, and therefore an error relative to the certified values, of 5-10 ΔE.

To address this issue, the virtual proofing system, as an option, should utilize not only the updated baseline profile, but also the original baseline profile that was used during SWOP certification in order to retain the original gamut size. The required preservation of gamut can be assured by adding an extra conversion to the existing process, RGB(original)->RGB(updated). This conversion can be combined or concatenated with existing conversions, or can be deployed as a final step for example by a viewing client just prior to displaying the RGB bitmap on screen. Example old and new color processing paths are:

Old: CMYK->RGB(display)

New: CMYK->RGB(display)->RGB(updated)

Old: CMYK->RGB(large gamut)->RGB(display)

New: CMYK->RGB(large gamut)->RGB(display)->RGB(updated)

Using spot measurement data of pure R, G, and B chromaticities compared with archived data taken with a spectrophotometer in order to estimate δxδy for R, G, and B, errors in the SWOP ADS procedure (measured with the colorimeter required by the procedure) were reduced from a max error of 8-10 ΔE down to a level of 2-3 ΔE. This good start indicates that the shifts observed are linear in nature and therefore correctable via the proposed method above. Visual assessment likewise confirmed reasonable results, thereby confirming the above-discussed assumptions that a simple RGB->(RGB)′ correction matrix is adequate to maintain color accuracy.

According to an embodiment of the present invention, the above step of directly measuring the shifts in RGB chromaticities is replaced by a step whereby the values of δx, δy for R, G, and B are estimated based on a least squares fit analysis of several measurements. The optimal choices for measurement device and data set are the ones required to perform the SWOP ADS procedure for the display being updated. An advantage of this approach is that the metric used to identify the problem (the results of the SWOP ADS procedure) is the same metric whose error is being minimized by the process. By definition, this will achieve the best possible numerical result. Concerns that might be raised are, for example, device-to-device errors in the local measurement device, even if it is the same model of device used to define the target L*a*b* values for the certification procedure. However, to the extent that these errors exist, they already impact the perceived functionality of the device by increasing the errors of the SWOP ADS procedure. An example of estimates for device-to-device variability are 2 ΔE (for the colorimeter used in the SWOP ADS procedure for MV) in the extreme R, G, and B colors. This error is reduced for the less saturated colors measured in the SWOP ADS procedure. Furthermore, the target reference values of the SWOP ADS procedure are generally obtained as an average of several displays and measurement devices—this should further minimize any negative impact of the device-to-device errors.

If future significant device-to-device errors arise, this should be addressed at the factory calibration procedure for the device, since this will cause the SWOP ADS procedure to fail even if this correction process is not deployed.

With the above background in mind, a process, according to an embodiment of the present invention will be described for detecting an unacceptable color shift when it occurs and automatically correcting the shift so as to ensure that the display in question is now in specification relative to a certification procedure.

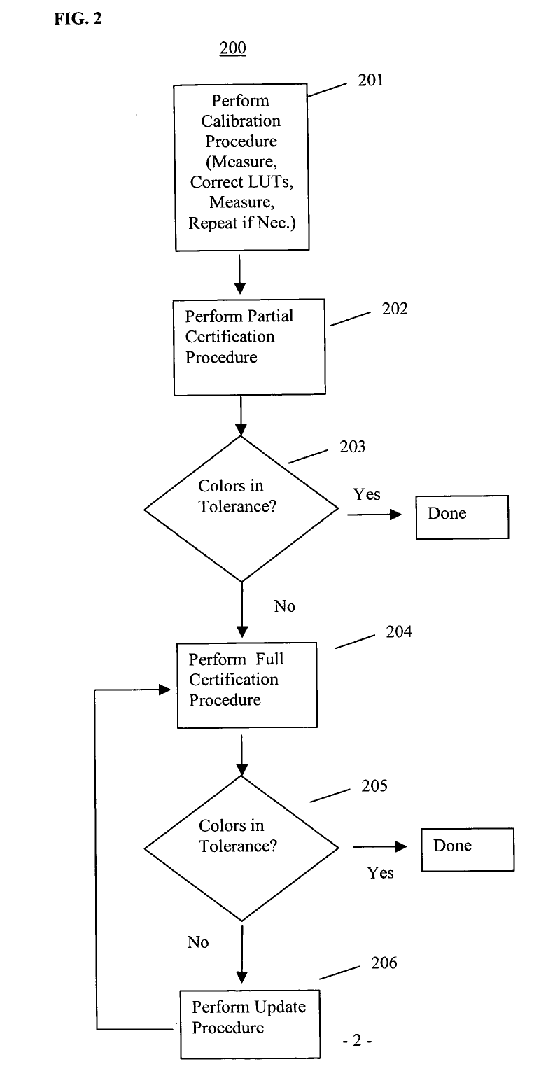

Such description begins with reference to FIG. 2. Step 201 represents a standard calibration procedure performed in order to keep the display 106 in specification, typically on a daily or weekly basis. According to an embodiment of the present invention, the procedure performed at step 201 is in the form of single channel adjustment.

Once the standard calibration procedure is completed, a partial certification process may be performed at step 202. An object of this procedure is to determine whether the display 106 exhibits a color shift that exceeds its color tolerance. The color tolerance of the display 106 may be determined by color tolerance information stored in the data storage system 104. The color shift may be determined by comparing measurements of colors displayed by the display 106 (referred to herein as “displayed color measurements”) to measurements of reference colors (referred to herein as “reference color measurements”), such as color patches used for a SWOP or other certification procedure. In particular, it is advantageous, at step 202, to measure as few colors displayed by the display 106 as possible in order to minimize the extra time necessary to measure, but enough colors to determine with confidence that the display 106 is within tolerance. Although the invention is not so limited, anywhere between approximately 3 and approximately 30 color patches corresponding to an additive color system may be measured.

According to an embodiment of the present invention, “within tolerance” means ‘conforms to the requirements of a particular certification process.’ If the certification process is the one defined in the SWOP ADS for the display, a reasonable determination can be made regarding the state of the display by measuring the RGB simulations of SWOP C, M, Y, R, G, B at (or approximately at) 100% or at (or approximately at) 75% and comparing those results to the corresponding target values contained in SWOP ADS (typically a set of 20 color patch measurements). It should be noted that, although the phrase “within tolerance” is used in the above exemplary embodiment to mean ‘conforms to the requirements of a particular certification process,’ one skilled in the art will appreciate that such phrase may, more generally, mean ‘within any predetermined error range or threshold.’

In step 203, the system 100 determines whether the partial set of certification colors are in tolerance. If the answer is yes, there is a high confidence factor that the display 106 is in an acceptable state, and the process is now complete. Customers viewing images and their remote collaborators can be confident of accurate color appearance.

If the partial set of certification values is not in tolerance, the system 100 may next perform a full certification procedure at step 204. The full certification procedure at step 204 may be performed the same as the partial certification procedure at step 202, but with more colors measured. If the colors are in tolerance after the full certification procedure as determined in step 205 (which can occur for example if the initial measurements were only slightly out of tolerance) the display in question is considered acceptable, and the process is finished.

If the measurements are not in tolerance at step 205 after performing a full certification procedure, the system 100 proceeds to use the full certification data to perform a moderate update procedure at step 206 that performs a moderate color correction to place the display 106 back into tolerance. According to an embodiment of the invention, the moderate update procedure at step 206 is performed only if the color shift measured at step 204 is less than or equal to approximately 15 ΔE to ensure that such moderate update procedure is capable of correcting such color shift. Conversely, the moderate update procedure at step 206, according to an embodiment of the present invention, is capable of correcting color shifts on the order of approximately 15 ΔE. After completing the update procedure at step 206, the system 100 returns to step 204 to perform a full certification procedure and confirm that the display 106 is now in an acceptable state.

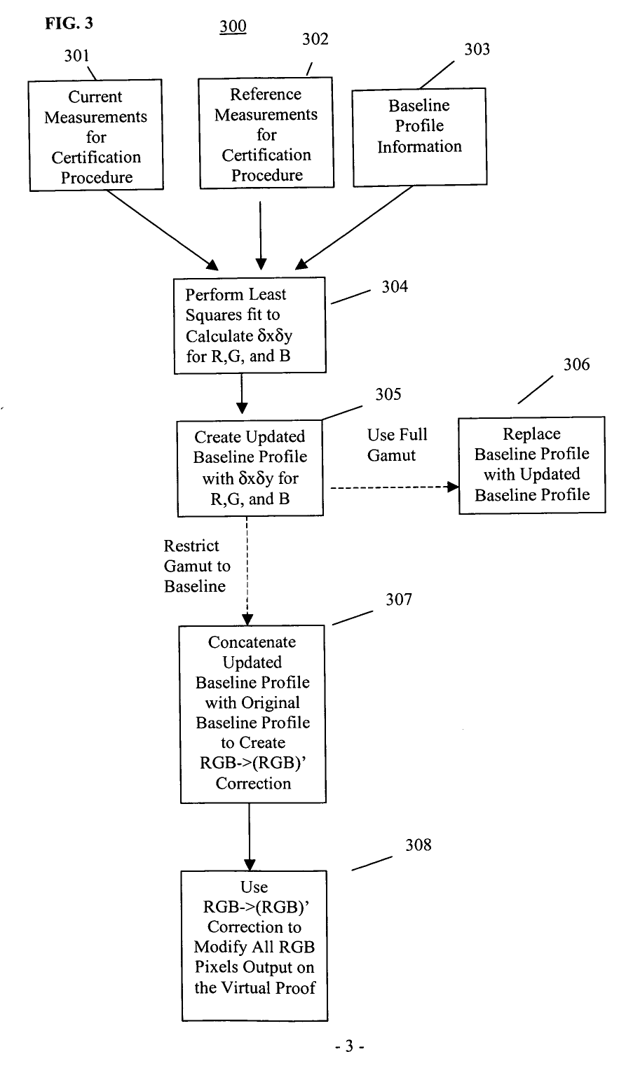

A moderate update procedure 300 that may be performed at step 206, according to an embodiment of the present invention, will now be described with reference to FIG. 3. Inputs to the update procedure includes the displayed color measurements 301, the reference color measurements 302, and the characterization and visual correction information of the baseline profile for the display 303 (referred to herein as “baseline profile information”).

In step 304, a small or moderate, such as a 3×3, RGB->(RGB)′ matrix correction is calculated. In one embodiment of the present invention, a calculation is performed to estimate the apparent shift in chromaticities δxδy of R, G, and B based on a least squares fit to the data. In order to perform the least squares fit analysis, the error function to be minimized is to be defined. In order to define the error function to be minimized, all values of L*a*b* (original target SWOP values and current SWOP measurements) are converted to XYZ using, for example, the Matchprint Virtual D50 visual white point defined for that display (xy_{wp}—which is typically significantly different from standard D50 xy):
XYZ=f_{XYZ->Lab}⁻¹(Lab,XYZ_{wp})
X_{wp}=x_{wp}Y_{wp}/y_{wp}=x_{wp}/y_{wp}
Y_{wp}=1
Z_{wp}=z_{wp}Y_{wp}/y_{wp}=(1−x_{wp}−y_{wp})/y_{wp} Eq. 10

The shift in XYZ that is expected due to the shifts δxδy of R, G, and B can be characterized by converting the original XYZ values to RGB using the inverse of the original RGB->XYZ matrix, then converting these values back to XYZ using a small or moderate matrix, such as a 3×3 matrix, corrected with the estimates of δxδy for R, G, and B:

$$( \begin{matrix}{X}^{′} \\ {Y}^{′} \\ {Z}^{′}\end{matrix} ) = M ( δ x , δ y ) {M}^{- 1} ( 0 , 0 ) ( \begin{matrix}X \\ Y \\ Z\end{matrix} ) \qquad Eq . 11$$

The above equation permits an error function that varies with δxδy:

$$\begin{matrix}Err ( δ x , δ y ) = {\sum }_{i = 0}^{i = N - 1} [ {f}_{XYZ \to Lab} ( {XYZ}_{i} ) - \\ {f}_{XYZ \to Lab} ( M ( δ x , δ y ) \\ { {M}^{- 1} ( 0 , 0 ) {XYZ}_{i 0} ) ]}^{2}\end{matrix} \qquad Eq . 12$$

where N is the number of colors measured (for example it may be that N=20 for the SWOP ADS procedure), XYZᵢ are the current measurements for those colors, and XYZᵢ₀ are the original reference measurements for those colors performed on the original population of displays used to create the baseline profile.

In the above calculation, for simplicity, it is assumed that a consistent value of XYZ_{wp} is used in the calculation of L*a*b* (namely the targeted white point of the display) and that by “δ×δy” it is meant δ×δy for R, for G, and for B.

Next, a least squares fit analysis is performed by an error minimization on Err( ). This analysis yields optimal estimates for δxδy for R, G, and B. Note that if there is no shift in the color characteristics of the display, Err( ) will be minimized for δxδy=0. Note that once optimal values of δxδy have been calculated, the individual ΔE's can be recalculated to obtain an expected value of average and max ΔE if the correction is deployed.

In step 305, the resulting calculated values of δxδy can now be incorporated into the expression for the visually corrected baseline profile which has been updated via measurement defined in equation 9. One of two options may be used depending on preferences for the design of the virtual proofing system, or based on selectable user preferences. The first option, indicated in final step 306, is to replace the existing baseline profile with the updated profile. This means that the full existing gamut of the display may be used for color rendering purposes. The second option, indicated in step 307, is to restrict the new gamut of the display to be no greater than the original gamut of the baseline profile. In this second case, an RGB->(RGB)′ correction matrix is calculated by concatenating the old and new profiles.

The corrected matrix M(δx,δy) can be used to create the RGB->(RGB)′ transform, correcting from old RGB values to new RGB values. The calculation for this transform may be:

$$\begin{matrix}( \begin{matrix}R \\ G \\ B\end{matrix} ) = ( \begin{matrix}f ( r , {γ}_{r} , {R}_{0} ) \\ f ( g , {γ}_{g} , {G}_{0} ) \\ f ( b , {γ}_{b} , {B}_{0} )\end{matrix} ) \\ ( \begin{matrix}{R}^{′} \\ {G}^{′} \\ {B}^{′}\end{matrix} ) = {M}^{- 1} ( δ x , δ y ) M ( 0 , 0 ) ( \begin{matrix}R \\ G \\ B\end{matrix} ) \\ ( \begin{matrix}{r}^{′} \\ {g}^{′} \\ {b}^{′}\end{matrix} ) = ( \begin{matrix}{f}^{- 1} ( {R}^{′} , {γ}_{r} , {R}_{0} ) \\ {f}^{- 1} ( {G}^{′} , {γ}_{g} , {G}_{0} ) \\ {f}^{- 1} ( {B}^{′} , {γ}_{b} , {B}_{0} )\end{matrix} ) \\ R = f ( r , {γ}_{r} , {R}_{0} ) \\ = {R}_{0} + ( 1 - {R}_{0} ) {r}^{{γ}_{r}} \\ r = {f}^{- 1} ( R , {γ}_{r} , {R}_{0} ) \\ = {( \frac{R - {R}_{0}}{1 - {R}_{0}} )}^{\frac{1}{{γ}_{r}}}\end{matrix} \qquad Eq . 13$$

Finally, in step 308, the calculation defined above is used to transform all display RGB pixels to new values (RGB)′. This conversion can take place as a post-processing step after the normal CMYK->RGB conversion is performed, or can be concatenated with the existing CMYK->RGB transform to create a new one step transform CMYK->(RGB)′

In following the above-discussed processes, a least squares fit indicated that the expected errors after correction for Apple Cinema 23 displays would be an average of 1, max of 2 ΔE. For a single worst case Eizo ColorEdge CG21 display that had been significantly aged, the average was 0.7, max 1.5 ΔE.

It is to be understood that the exemplary embodiments are merely illustrative of the present invention and that many variations of the above-described embodiments can be devised by one skilled in the art without departing from the scope of the invention. For example, although FIG. 2 illustrates the separate performance of a partial certification procedure at step 202 and a full certification procedure at step 204, one skilled in the art will appreciate that one, or more than two, certification step(s) may be instead performed prior to performing an update, if necessary, at step 206. Further, although the invention often describes the use of certification procedures used as part of tolerance and other testing, one skilled in the art will appreciate that such certification procedures are only described as being a convenient way to perform such testing. However, such tolerance or other testing may be performed with respect to any other standards or criteria, and need not be performed with respect to certification procedures. It is therefore intended that any and all such variations be included within the scope of the following claims and their equivalents.

### PARTS LIST

100 system
101 computer
102 input source
103 video card
104 data storage system
105 color measurement device
106 display
107 output source
200 method
201-206 steps
300 method
301 displayed color measurements
302 reference color measurements
303 baseline profile information
304-308 steps

What is claimed is:

1. A computer-implemented method for maintaining accurate color performance of a display, the method comprising the steps of:
receiving reference color measurements;
receiving displayed color measurements from the display corresponding to the reference color measurements, wherein the display is an additive-color-based display;
receiving color tolerance information for the display;
determining a color shift based at least upon the reference color measurements and the displayed color measurements;
determining whether the color shift exceeds a color tolerance of the display based at least upon the color tolerance information;
if it is determined that the color shift exceeds the color tolerance of the display, the method further comprises the steps of:
receiving baseline profile information for the display; and
performing a moderate color correction to the baseline profile information for the display, thereby generating updated baseline profile information for the display.

2. The method of claim 1, wherein the display is an RGB display.

3. The method of claim 1, wherein the reference color measurements are based at least upon measurements of color patches.

4. The method of claim 3, wherein the color patches number anywhere from approximately 3 color patches to approximately 30 color patches.

5. The method of claim 3, wherein the color patches correspond to an additive color system.

6. The method of claim 3, wherein the color patches are used for a color certification.

7. The method of claim 6, wherein the color certification is a SWOP certification.

8. The method of claim 1, wherein the determined color shift is less than or equal to approximately 15 ΔE.

9. The method of claim 1, wherein the step of determining the color shift comprises performing a least squares fit to determine an overall color shift in red, green, and blue, and wherein the step determining whether the color shift exceeds the color tolerance of the display comprises determining whether the color shift exceeds the color tolerance of the display based at least upon the color tolerance information and the overall color shift.

10. The method of claim 9, wherein the color tolerance information corresponds to color certification standards.

11. The method of claim 10, wherein the color certification standards are SWOP standards.

12. The method of claim 9, wherein the moderate color correction performed is determined based at least upon the determined overall color shift.

13. The method of claim 1, wherein the color tolerance information corresponds to color certification standards.

14. The method of claim 13, wherein the color certification standards are SWOP standards.

15. The method of claim 1, wherein the step of determining whether the color shift exceeds the color tolerance of the display determines whether the color shift exceeds the color tolerance of the display for both chromatic and neutral colors.

16. The method of claim 1, wherein the moderate color correction is a small or moderate RGB->(RGB)′ matrix correction.

17. The method of claim 16, wherein the RGB->(RGB)′ matrix correction is a 3×3 RGB->(RGB)′ matrix correction.

18. The method of claim 1, wherein the moderate color correction performed is determined based at least upon the determined color shift.

19. The method of claim 1, wherein if it is determined that the color shift exceeds the color tolerance of the display, and if a full gamut of the display is to be used, the method further comprises the steps of:
receiving second displayed color measurements from the display corresponding to the reference color measurements, the second displayed color measurements being measured using the updated baseline profile information for the display;
determining a second color shift based at least upon the reference color measurements and the second displayed color measurements;
determining whether the second color shift exceeds the color tolerance of the display based at least upon the color tolerance information; and
if it is determined that the second color shift does not exceed the color tolerance of the display, replacing the baseline profile information with the updated baseline profile information.

20. The method of claim 1, wherein if it is determined that the color shift exceeds the color tolerance of the display, and if a gamut of the display is to be restricted to a baseline gamut, the method further comprises the steps of:
receiving second displayed color measurements from the display corresponding to the reference color measurements, the second displayed color measurements being measured using the updated baseline profile information for the display;
determining a second color shift based at least upon the reference color measurements and the second displayed color measurements;
determining whether the second color shift exceeds the color tolerance of the display based at least upon the color tolerance information; and
if it is determined that the second color shift does not exceed the color tolerance of the display, concatenating the updated baseline profile information with the baseline profile information.

21. One or more computer-accessible memories storing computer code for implementing a method for maintaining accurate color performance of a display, wherein the computer code comprises:
code for receiving reference color measurements;
code for receiving displayed color measurements from the display corresponding to the reference color measurements, wherein the display is an additive-color-based display;
code for receiving color tolerance information for the display;
code for determining a color shift based at least upon the reference color measurements and the displayed color measurements;
code for determining whether the color shift exceeds a color tolerance of the display based at least upon the color tolerance information;
code for receiving baseline profile information for the display, if it is determined that the color shift exceeds the color tolerance of the display; and
code for performing a moderate color correction to the baseline profile information for the display, thereby generating updated baseline profile information for the display, if it is determined that the color shift exceeds the color tolerance of the display.

22. The one or more computer-accessible memories of claim 21, wherein the display is an RGB display.

23. The one or more computer-accessible memories of claim 21, wherein the reference color measurements are based at least upon measurements of color patches, wherein the color patches number anywhere from approximately 3 color patches to approximately 30 color patches.

24. The one or more computer-accessible memories of claim 21, wherein the reference color measurements are based at least upon measurements of color patches, and wherein the color patches are used for a color certification.

25. The one or more computer-accessible memories of claim 21, wherein the determined color shift is less than or equal to approximately 15 ΔE.

26. The one or more computer-accessible memories of claim 21, wherein the code for determining the color shift comprises code for performing a least squares fit to determine an overall color shift in red, green, and blue, wherein the code for determining whether the color shift exceeds the color tolerance of the display comprised code for determining whether the color shift exceeds the color tolerance of the display based at least upon the color tolerance information and the overall color shift, and wherein the code for performing the moderate color correction performs the moderate color correction based at least upon the determined overall color shift.

27. The one or more computer-accessible memories of claim 21, wherein the moderate color correction is a small or moderate RGB->(RGB)′ matrix correction.
